(19) United States
(12) Patent Application Publication
(10) Pub. No.: US 2008/0122060 A1
(43) Pub. Date: May 29, 2008

(54) SEMICONDUCTOR DEVICE INCLUDING CORROSION RESISTANT WIRING STRUCTURE

(75) Inventors: Yoichi NOGAMI, Tokyo (JP); Koichi FUJITA, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/558,056

(22) Filed: Nov. 9, 2006

(30) Foreign Application Priority Data
Jun. 15, 2006 (JP) 2006-165844

(51) Int. Cl. H01L 23/48

(52) U.S. Cl. 257/690; 257/E23.18

(57) ABSTRACT

A semiconductor device packaged in a non-hermetic package includes a semiconductor substrate; a wiring metal film on the semiconductor substrate; a plating power supply film on the wiring metal film; an Au plated portion on the plating power supply film; a metal film covering the Au plated portion; and an insulating protective film covering the metal film. The metal film is a material having corrosion resistance properties such that a potential-pH diagram of the metal material predominantly includes a corrosion-free region and a passive region and either does not include a corrosion region or includes a very small corrosion region, the potential-pH diagram showing the effects of electrical potential and pH on corrosion of the metal material.

### FIELD OF THE INVENTION

The present invention relates to a semiconductor device packaged in a non-hermetic package, and more particularly to a semiconductor device with enhanced moisture resistance in which degradation of Au plating due to ion migration is prevented.

### BACKGROUND ART

A conventional manufacturing process for a semiconductor device will be described with reference to the accompanying drawings. First, as shown in FIG. 30, a transistor portion is formed on a semiconductor substrate 11 in a predetermined manner. The transistor portion is made up of a gate electrode 12, ohmic electrodes 13 (drain, source), and wiring metal films 14. Then, an insulating protective film 15 (e.g., an SiN film, SiON film, or SiO film) is formed on the entire surface by plasma CVD, and contact holes are formed in the portions of the insulating protective film 15 on the wiring metal films 14. These contact holes are used to bond (or deposit) Au plating portions onto the wiring metal films 14 at a subsequent step.

Then, as shown in FIG. 31, a lower layer resist pattern 16 is formed that has openings exposing the above contact holes. After that, a Ti film 17 and an Au film 18 are formed as plating power supply layers by sputtering, as shown in FIG. 32. Further, as shown in FIG. 33, an upper layer resist pattern 19 is formed that has openings in which the Au plating portions are later formed.

Then, Au is deposited in the openings in the upper layer resist pattern 19 by electroplating, forming the Au plating portions 20, as shown in FIG. 34. Then, after removing the upper layer resist pattern 19, as shown in FIG. 35, the unwanted portions of the plating power supply layers are removed by ion milling and the lower layer resist pattern 16 is also removed, as shown in FIG. 36.

Then, a plasma CVD film 21 of SiN or SiON is formed by plasma CVD as an insulting protective film to protect the entire surface, as shown in FIG. 37. After that, a portion of the plasma CVD film 21 in the bonding pad region is removed to form an opening. It should be noted that instead of the plasma CVD film 21, a resin coating film 22 (of polyimide, etc.) may be formed as the insulating protective film, as shown in FIG. 38.

In conventional semiconductor devices, the plasma CVD film 21 or the resin coating film 22 is directly formed on the Au plating portions 20, as described above. In such a case, however, since the adhesion between the Au plating portions 20 and the plasma CVD film 21 or the resin coating film 22 is poor, film peeling (or delamination) and hence penetration of moisture are likely to occur at their interface. Therefore, a semiconductor device packaged in a non-hermetic package such as a plastic package or a molded package has the problem of reduced moisture resistance. It should be noted that the above problems (film peeling and penetration of moisture) also occur at the interface between the semiconductor substrate 11 and the open end portion of the plasma CVD film 21 or the resin coating film 22 in the chip isolation region.

Furthermore, when a high voltage is applied to a semiconductor device that contains moisture (as a result of a reduction in its moisture resistance), the problem of ion migration may occur. FIG. 39 is a potential-pH diagram of Au, showing the effects of electrical potential and pH on Au corrosion, wherein the vertical axis represents electrical potential and the horizontal axis represents pH. FIG. 40 is a potential-pH diagram of Ti, showing the effects of electrical potential and pH on Ti corrosion. (See, e.g., M. Pourbaix, “Atlas of Electrochemical Equilibria in Aqueous Solutions”, NACE, Houston, 1966.) FIGS. 39 and 40 indicate that when a high electric field is applied to the positive electrode of a conventional semiconductor device, the Ti film 17, the Au film 18 and the Au plating portions 20 are under conditions represented by the corrosion regions (or corrosion prone regions) in these figures. Therefore, when a conventional semiconductor device is operated at a high power level, Ti and Au on the ohmic electrodes in the transistor portion dissolve due to ion migration caused by application of a high bias and penetration of moisture, resulting in degradation of the device.

It should be noted that FIG. 41 is a potential-pH diagram of Mo showing the effects of electrical potential and pH on Mo corrosion and FIG. 42 is a potential-pH diagram of W showing the effects of electrical potential and pH on W corrosion, As shown in these figures, if Mo or W is used instead of Ti, ion migration occurs due to penetration of moisture even when the device is not operated at a high power level.

### SUMMARY OF THE INVENTION

The present invention has been devised to solve the above problems. It is, therefore, an object of the present invention to provide a semiconductor device with enhanced moisture resistance in which degradation of Au plating due to ion migration is prevented.

According to one aspect of the present invention, a semiconductor device packaged in a non-hermetic package includes a semiconductor substrate; a wiring metal film formed on the semiconductor substrate; a plating power supply film formed on the wiring metal film; an Au plating portion formed on the plating power supply film; a metal film covering the Au plating portion; and an insulating protective film covering the metal film; wherein the metal film is formed of a material whose corrosion resistance properties are such that a potential-pH diagram of the metal material predominantly includes a corrosion-free region and a passive region and either does not include a corrosion region or includes a very small corrosion region, the potential-pH diagram showing the effects of electrical potential and pH on corrosion of said metal material.

The present invention allows the adhesive strength between the metal film and the insulating protective film to be increased, which prevents film peeling and penetration of moisture at the interface and thereby enhances the moisture resistance. Further, since the metal film covering the Au plating portion is highly corrosion resistant, it is possible to prevent degradation of the Au plating portion due to ion migration even in a high-power semiconductor device.

Other and further objects, features and advantages of the invention will appear more fully from the following description.

### BRIEF DESCRIPTION OF THE DRAWINGS

FIGS. 1-12 are sectional views for explaining a method of manufacturing a semiconductor device according to First Embodiment of the present invention.

FIG. 13 is a potential-pH diagram of Ta.

FIG. 14 is a potential-pH diagram of Nb.

FIG. 15 is a potential-pH diagram of Pt.

FIG. 16 is a potential-pH diagram of Rh.

FIGS. 17-23, 25-26, 28-29 are sectional views for explaining a method of manufacturing a semiconductor device according to First Embodiment of the present invention.

FIGS. 24, 27 are top views for explaining a method of manufacturing a semiconductor device according to First Embodiment of the present invention.

FIGS. 30-38 are sectional views for explaining a conventional manufacturing process for a semiconductor device.

FIG. 39 is a potential-pH diagram of Au.

FIG. 40 is a potential-pH diagram of Ti.

FIG. 41 is a potential-pH diagram of Mo.

FIG. 42 is a potential-pH diagram of W.

### DETAILED DESCRIPTION OF THE PREFERRED EMBODIMENTS

### First Embodiment

A first embodiment of the present invention relates to a semiconductor device packaged in a non-hermetic package such as a plastic package or a molded package. A process for manufacturing this semiconductor device will be described with reference to FIGS. 1 to 12.

As shown in FIG. 1, a transistor portion is formed on a semiconductor substrate 11 in a predetermined manner. The transistor portion is made up of a gate electrode 12, ohmic electrodes 13 (drain, source), and wiring metal films 14. Then, an insulating protective film 15 (e.g., an SiN film, SiON film, or SiO film) is formed on the entire surface by plasma CVD, and contact holes are formed in the portions of the insulating film 15 on the wiring metal films 14. These contact holes are used to deposit Au plating portions onto the wiring metal film 14 at a subsequent step.

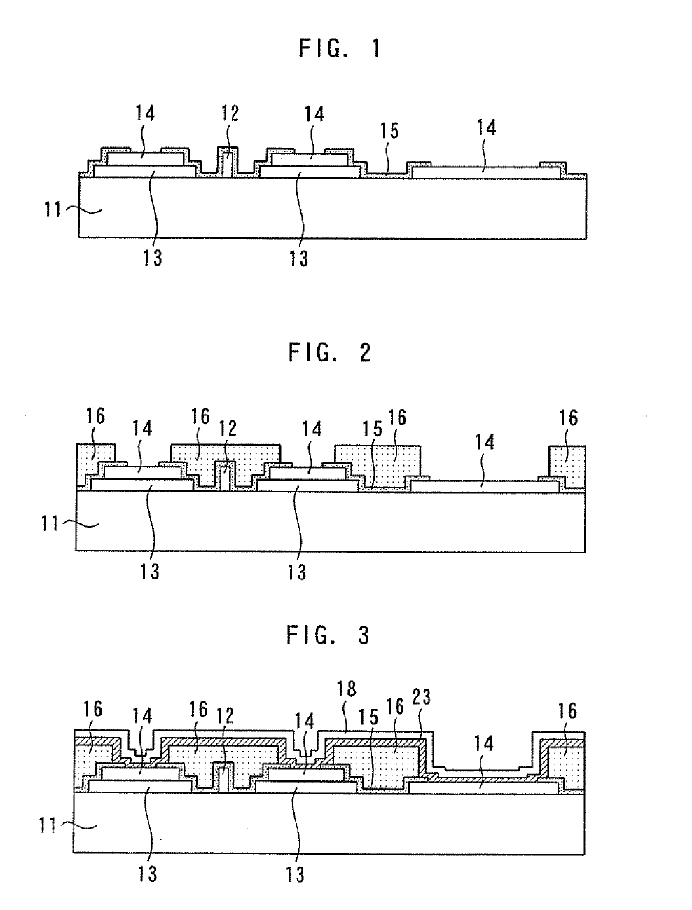

As shown in FIG. 2, a lower layer resist pattern 16 is formed that has openings exposing the above contact holes. These openings in the lower layer resist pattern 16 are formed to be larger than the contact holes in the insulating protective film 15. This allows the Au plating portions to be formed at a subsequent step such that they partially lie on the insulating protective film 15, thereby preventing penetration of moisture into the wiring metal films 14 and the ohmic electrodes 13 under the Au plating portions.

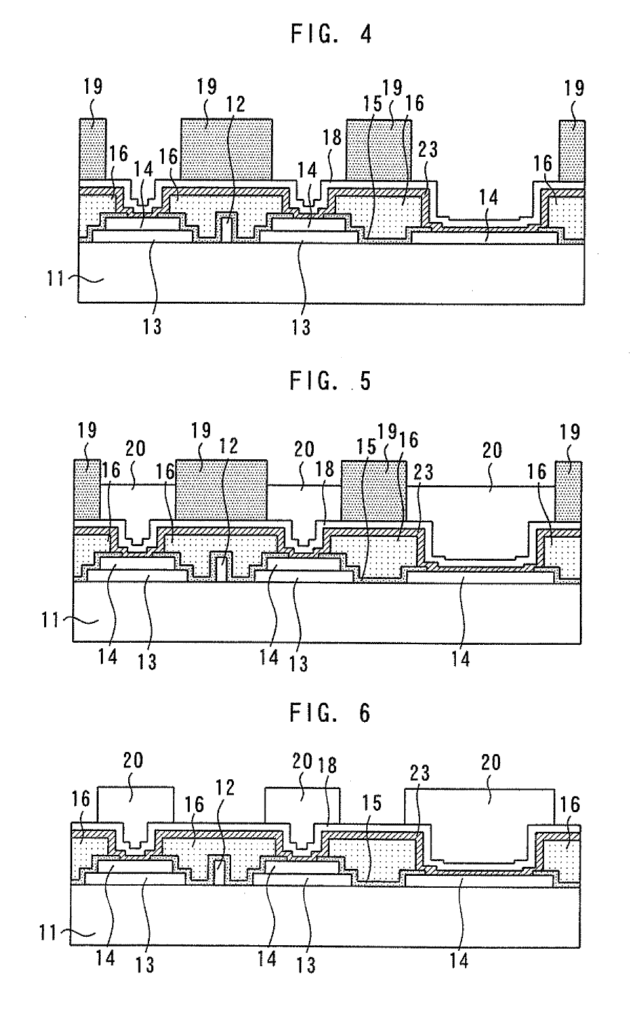

Then, a Ta film 23 and an Au film 18 are formed as plating power supply layers by sputtering, as shown in FIG. 3. After that, as shown in FIG. 4, an upper layer resist pattern 19 is formed that has openings in which the Au plating portions are later formed.

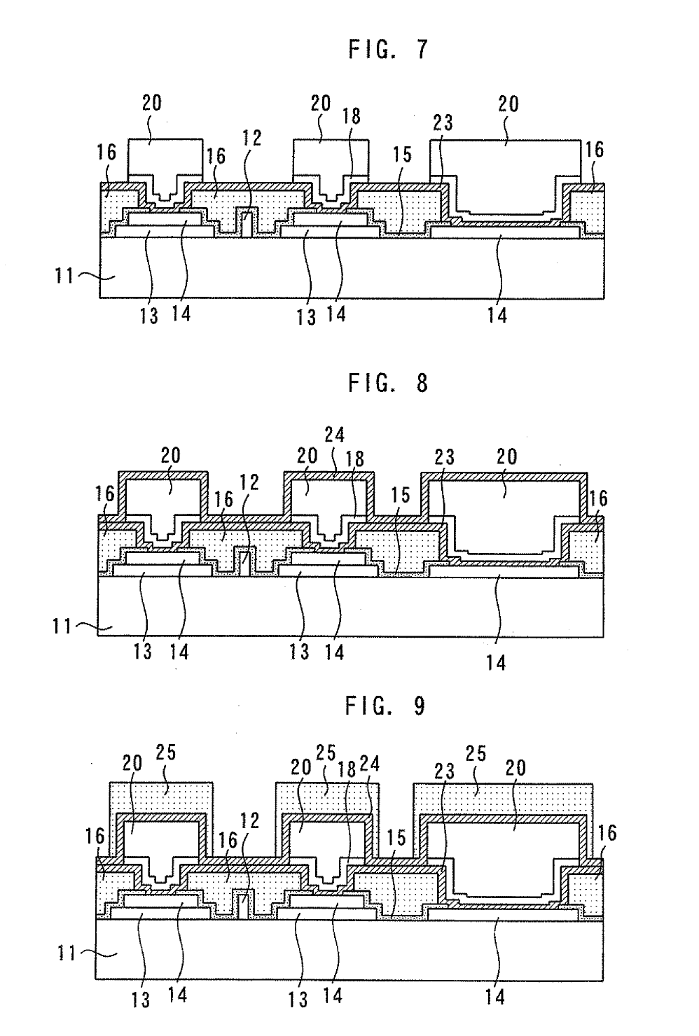

Then, Au is deposited in the openings in the upper layer resist pattern 19 by electroplating, forming the Au plating portions 20, as shown in FIG. 5. Then, after removing the upper layer resist pattern 19, as shown in FIG. 6, the unwanted portions of the Au film 18 are removed by use of an Au etchant (a mixed aqueous solution of iodine and potassium iodine), as shown in FIG. 7.

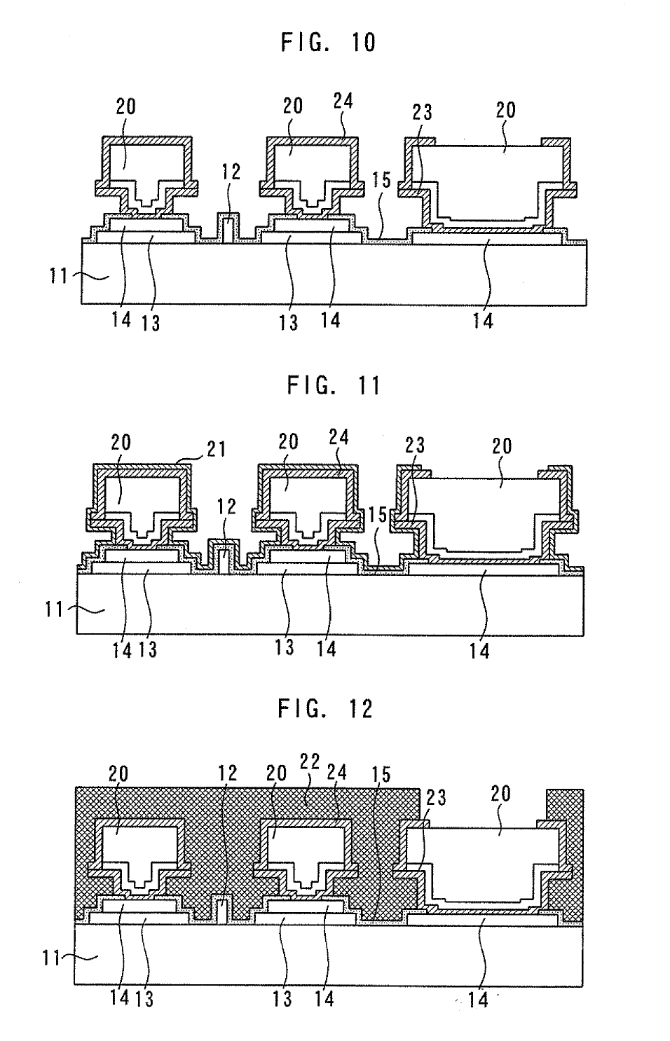

As shown in FIG. 8, a Ta film 24 is formed on the entire surface by sputtering. After that, a resist 25 is formed to cover only the Au plating portions 20, as shown in FIG. 9. Further, the unwanted portions of the Ta films 23 and 24 are removed by ion milling, and the resist 25 and the lower layer resist pattern 16 are also removed. (The Au plating portions 20 are completely covered by the Ta films 23 and 24.) Then, a portion of the Ta film 24 on the Au plating portion 20 in the bonding pad region is removed, forming an opening.

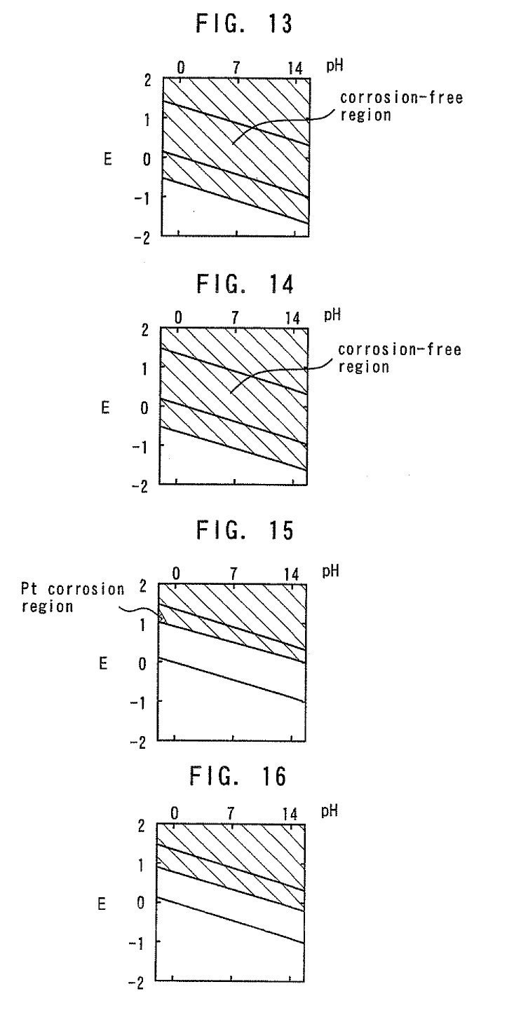

Then, a plasma CVD film 21 of SiN or SiON is formed by plasma CVD to protect the entire surface, as shown in FIG. 11. After that, a portion of the plasma CVD film 21 on the Au plating portion 20 in the bonding pad region is removed, forming an opening. It should be noted that instead of the plasma CVD film 21, a resin coating film 22 (of polyimide, etc.) may be formed as the insulating protective film, as shown in FIG. 12.

The semiconductor device of the present embodiment, manufactured by the above process, includes: the semiconductor substrate 11; the wiring metal films 14 formed on the semiconductor substrate 11; the Ta film 23 (a plating power supply film) formed on the wiring metal films 14; the Au plating portions 20 formed on the Ta film 23; the Ta film 24 (a metal film) covering the Au plating portions 20; and the plasma CVD film 21 or the resin coating film 22 (an insulating protective film) covering the Ta film 24.

The Au plating portions 20 are covered by the Ta films 23 and 24. Since Ta has higher adhesive strength to the plasma CVD film 21 or the resin coating film 22 than Au, the Ta films provide increased adhesive strength to these insulating protective films, which prevents film peeling and penetration of moisture at the interface at a subsequent step and thereby enhances the moisture resistance.

FIG. 13 is a potential-pH diagram of Ta, showing the effects of electrical potential and pH on Ta corrosion. This diagram includes only a passive region and a corrosion-free region and does not include a corrosion region (or corrosion prone region). (Thus, this metal material does not assume a corrosion prone state.) Therefore, covering the Au plating portions 20 with a highly corrosion-resistant Ta film prevents degradation of these Au plating portions due to ion migration even in a high-power semiconductor device.

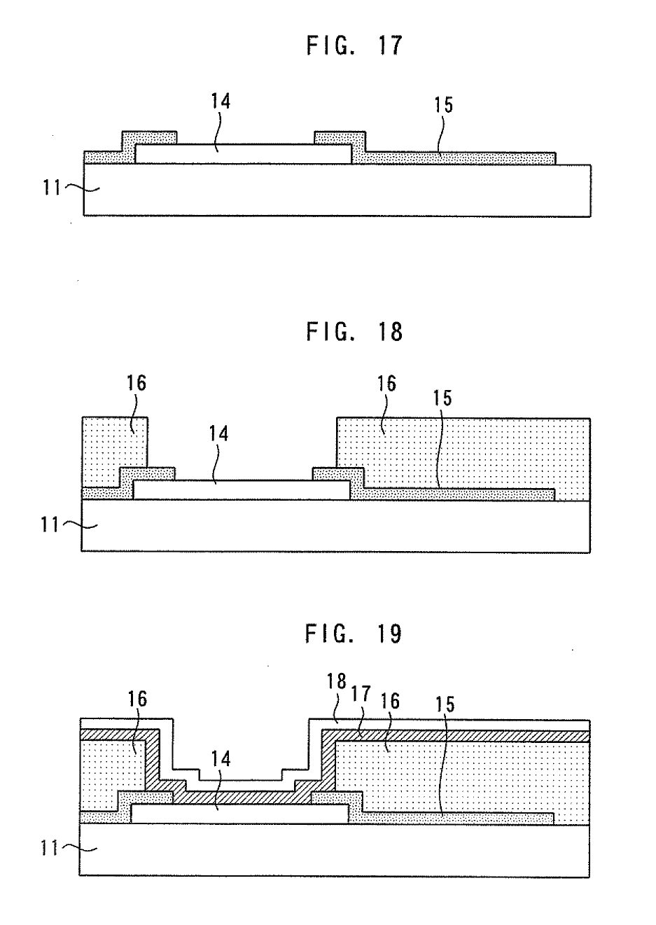

Further, FIG. 14 is a potential-pH diagram of Nb, showing the effects of electrical potential and pH on Nb corrosion; FIG. 15 is a potential-pH diagram of Pt, showing the effects of electrical potential and pH on Pt corrosion; and FIG. 16 is a potential-pH diagram of Rh, showing the effects of electrical potential and pH on Rh corrosion. These diagrams predominantly include a passive region and a corrosion-free region and either do not include a corrosion region or include a very small corrosion region. (Thus, these metal materials are highly corrosion resistant.) Therefore, the plating power supply film and the metal film may be formed of Nb, Pt, or Rh, instead of Ta.

Further, the surfaces of the Ta films 23 and 24 are preferably oxidized by an oxidation process using an oxygen asher, etc. This allows a passive film to be effectively formed on the exposed surfaces of the Ta films 23 and 24, further enhancing the adhesive strength between the Ta films and the plasma CVD film 21 or the resin coating film 22.

Still further, nitrogen gas is preferably added to the Ta film forming processes so as to form metal nitride films (TaN films), instead of the Ta films 23 and 24. This further enhances the adhesive strength to the plasma CVD film 21 or the resin coating film 22.

### Second Embodiment

A second embodiment of the present invention relates to a semiconductor device operated at a voltage low enough to substantially eliminate the problem of ion migration. A process for manufacturing this semiconductor device will be described with reference to FIGS. 17 to 29.

As shown in FIG. 17, a transistor portion is formed on a semiconductor substrate 11 in a predetermined manner. The transistor portion is made up of a gate electrode 12, ohmic electrodes 13 (drain, source), and a wiring metal film 14. It should be noted that the gate electrode 12 and the ohmic electrodes 13 are not shown in FIG. 17 and subsequent figures (and not described), since they are the same as in the first embodiment. Then, an insulating protective film 15 (e.g., an SiN film, SiON film, SiO film) is formed on the entire surface by plasma CVD, and a contact hole is formed in the portion of the insulating film 15 on the wiring metal film 14. This contact hole is used to deposit an Au plating portion onto the wiring metal film 14 at a subsequent step.

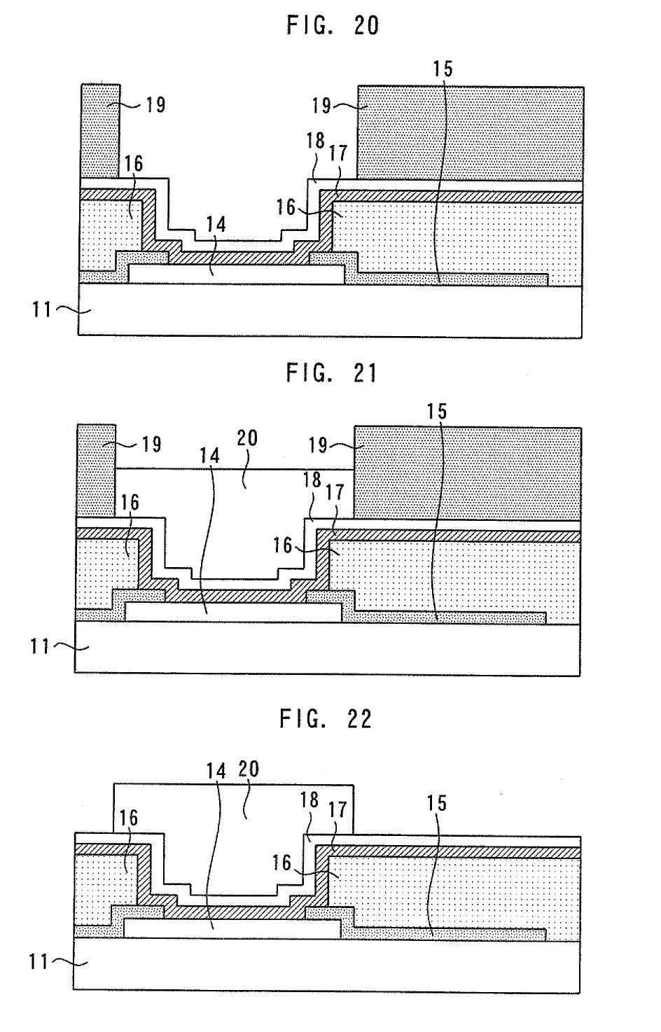

As shown in FIG. 18, a lower layer resist pattern 16 is formed that has an opening exposing the above contact hole. After that, a Ti film 17 and an Au film 18 are formed as plating power supply layers by sputtering, as shown in FIG. 19. Further, an upper layer resist pattern 19 is formed that has an opening in which the Au plating portion is later formed, as shown in FIG. 20.

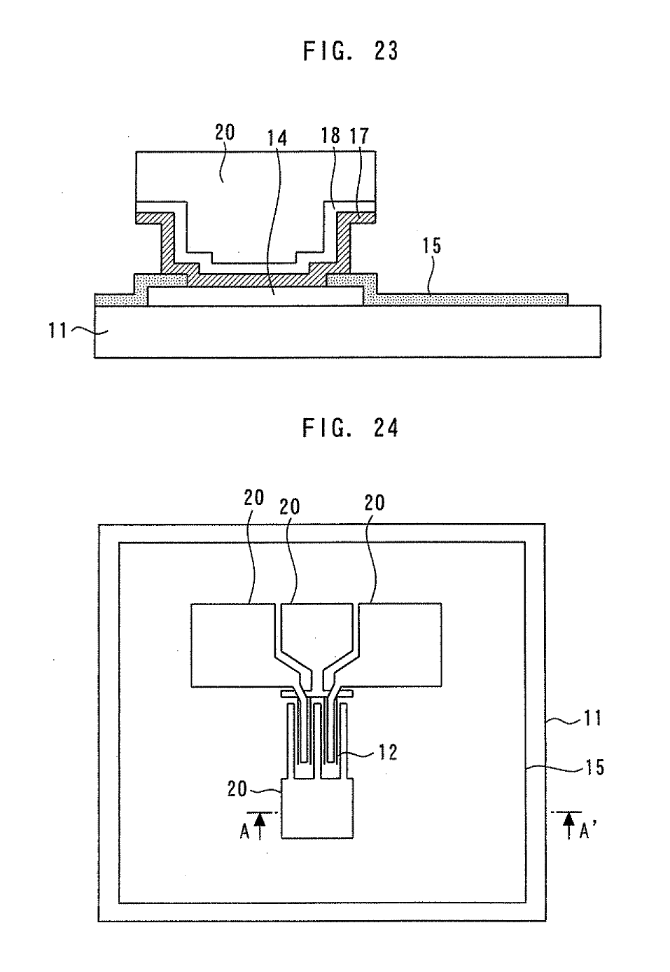

Then, Au is deposited in the opening in the upper layer resist pattern 19 by electroplating, forming the Au plating portion 20, as shown in FIG. 21. After removing the upper layer resist pattern 19, as shown in FIG. 22, the unwanted portions of the plating power supply layers are removed by ion milling and the lower layer resist pattern 16 is also removed, as shown in FIG. 23. FIG. 24 is a plan view of the semiconductor device after the above step. It should be noted that FIG. 23 is a cross-sectional view taken along line A-A′ of FIG. 24.

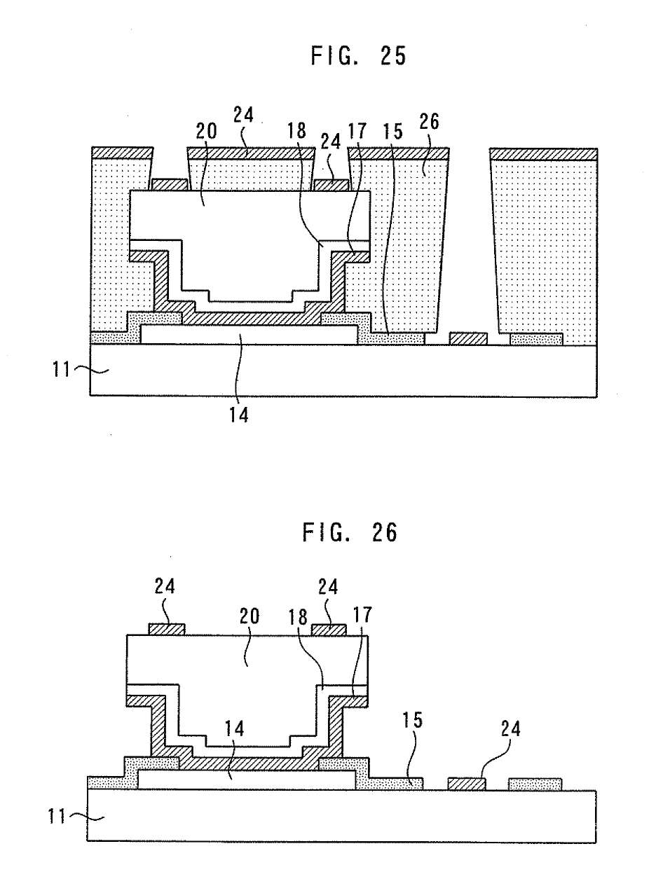

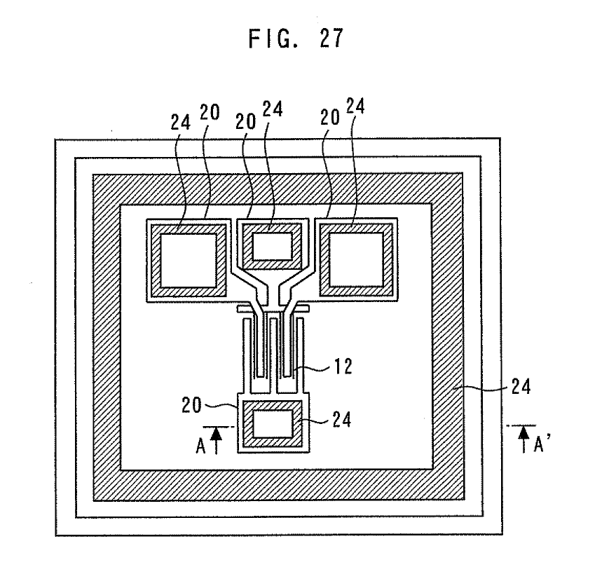

Then, a resist 26 is formed on the entire surface, and openings are formed in portions of the resist 26 on the Au plating portion 20 and on the peripheral portion of the semiconductor device. Further, the insulting (protective) film in the opening in the peripheral portion of the semiconductor device is removed by treatment with hydrofluoric acid, etc., and then Ta films 24 is deposited, as shown in FIG. 25. After that, the resist 26 is removed by a lift-off technique, leaving Ta films 24 as shown in FIG. 26. FIG. 27 is a plan view of the semiconductor device after the above step. It should be noted that FIG. 26 is a cross-sectional view taken along line A-A′ of FIG. 27.

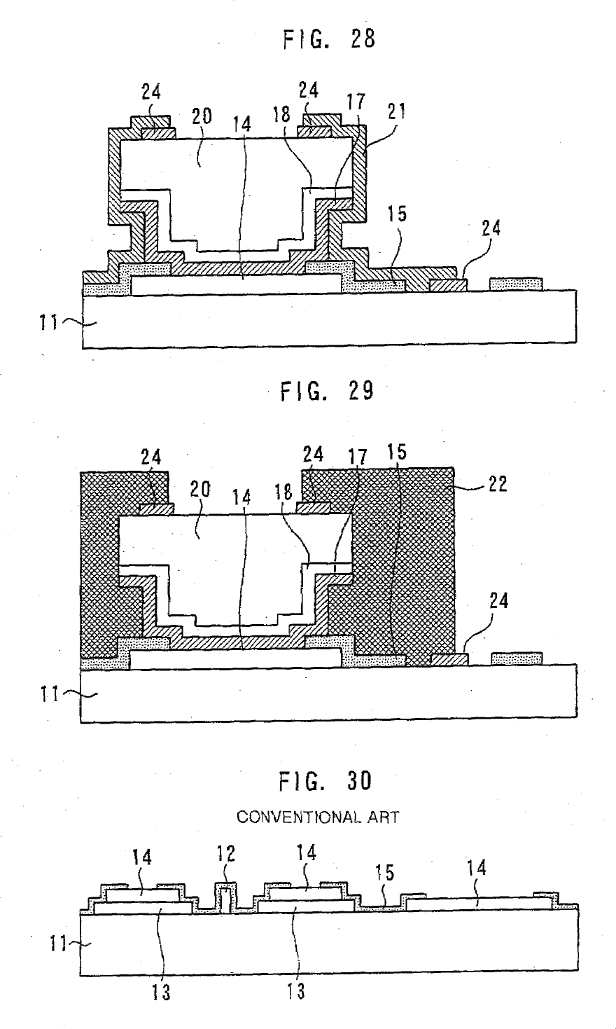

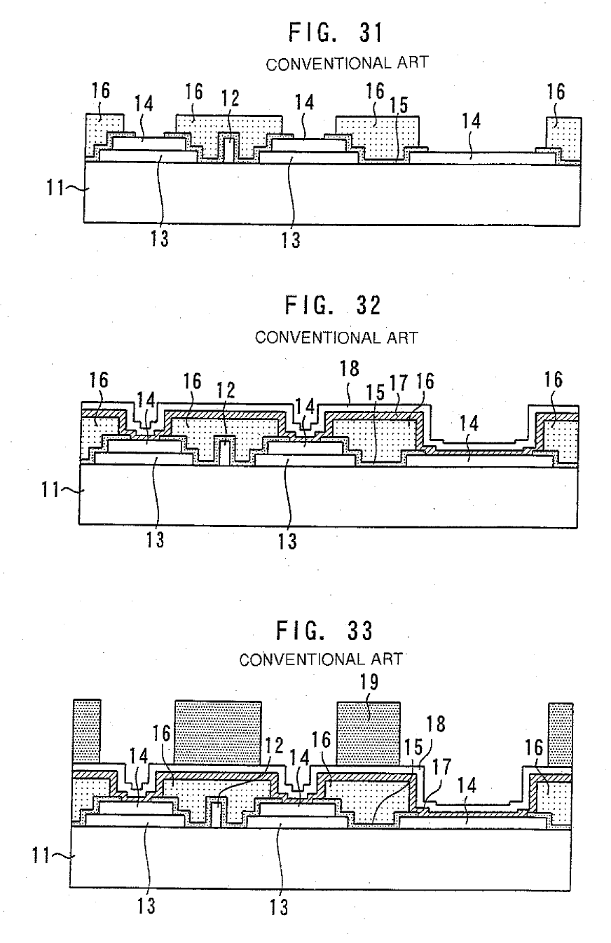

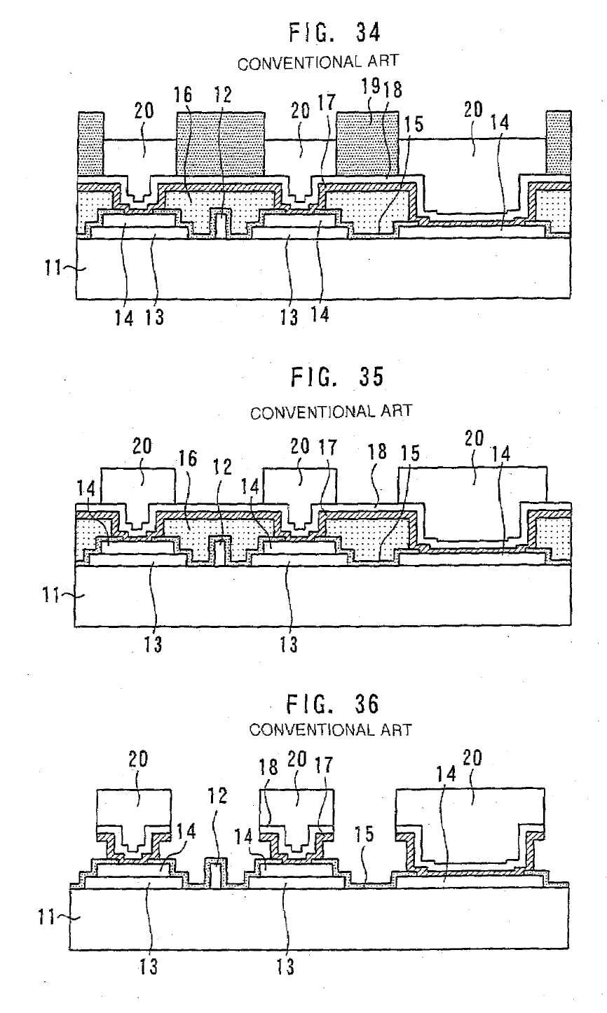

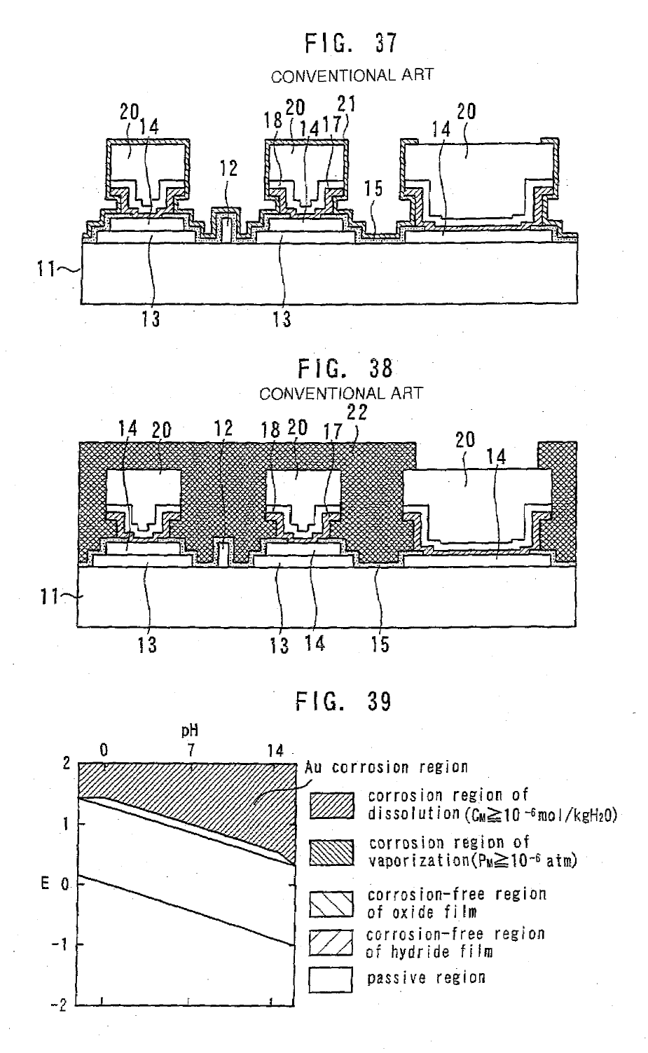

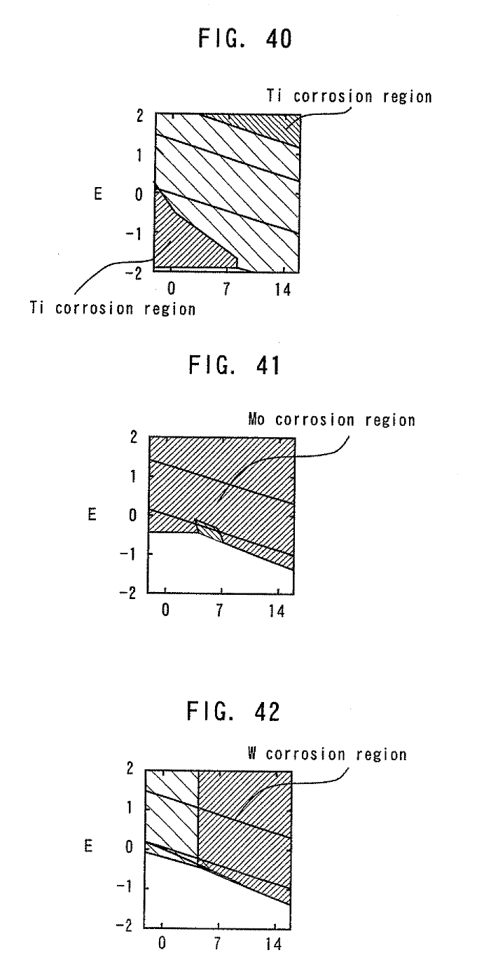

Then, a plasma CVD film 21 of SiN or SiON is formed by plasma CVD to protect the entire surface, as shown in FIG. 28. After that, a portion of the plasma CVD film 21 in the bonding pad region is removed to form an opening. It should be noted that instead of the plasma CVD film 21, a resin coating film 22 (of polyimide, etc.) may be formed as the insulating protective film, as shown in FIG. 29.

Thus, in the semiconductor device of the present embodiment (manufactured by the above process), the Au plating portion 20 is covered with a Ta film 24. Further, a Ta film 24 underlies the open end portion of the plasma CVD film 21 or the resin coating film 22 in the chip isolation region. Since Ta has higher adhesive strength to the plasma CVD film 21 or the resin coating film 22 than Au, the Ta films provide increased adhesive strength to these insulating protective films, which prevents film peeling and penetration of moisture at the interface at a subsequent step and thereby enhances the moisture resistance. Although the plating power supply films of the semiconductor device of the present embodiment are not formed of Ta, the device has sufficient moisture resistance since it is operated at a voltage low enough to substantially eliminate the problem of ion migration.

Further, metal films formed of Nb, Pt, or Rh may be used instead of the Ta films. Further, the surfaces of the Ta films 24 are preferably oxidized by an oxidation process using an oxygen asher, etc. This allows a passive film to be effectively formed on the exposed surfaces of the Ta films 24, further enhancing the adhesive strength between the Ta films 24 and the plasma CVD film 21 or the resin coating film 22. Still further, nitrogen gas is preferably added to the Ta film forming process so as to form metal nitride films (TaN films), instead of the Ta films 24. This further enhances the adhesive strength to the plasma CVD film 21 or the resin coating film 22.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2006-165844, filed on Jun. 15, 2006 including specification, claims, drawings and summary, on which the Convention priority of the present application is based, are incorporated herein by reference in its entirety.

1. A semiconductor device packaged in a non-hermetic package, said semiconductor device comprising:
a semiconductor substrate;
a wiring metal film on said semiconductor substrate;
a plating power supply film on said wiring metal film;
an Au plated portion on said plating power supply film;
a metal film covering said Au plated portion; and
an insulating protective film covering said metal film, wherein said metal film is a metal material having corrosion resistance properties and includes a metal selected from the group consisting of Ta, Pt, Rh, and Nb.

2. The semiconductor device as claimed in claim 1, wherein a surface of said metal film is oxidized.

3. The semiconductor device as claimed in claim 1, wherein said metal film is a nitride of the metal selected from the group consisting of Ta, Pt, Rh, and Nb.

4. The semiconductor device as claimed in claim 1, wherein said plating power supply film is a metal material having corrosion resistance properties and includes a metal selected from the group consisting of Ta, Pt, Rh, and Nb.

5. The semiconductor device as claimed in claim 4, wherein a surface of said plating power supply film is oxidized.

6. The semiconductor device as claimed in claim 4, wherein said plating power supply film is a nitride of the metal selected from the group consisting of Ta, Pt, Rh, and Nb.
